(19) United States
(12) Patent Application Publication
(10) Pub. No.: US 2014/0060607 A1
(43) Pub. Date: Mar. 6, 2014

(54) FLEXIBLE POLYMER-BASED THERMOELECTRIC MATERIALS AND FABRICS INCORPORATING THE SAME

(71) Applicants: Yue Wu, West Lafayette, IN (US); Scott Finefrock, West Lafayette, IN (US)

(72) Inventors: Yue Wu, West Lafayette, IN (US); Scott Finefrock, West Lafayette, IN (US)

(73) Assignee: PURDUE RESEARCH FOUNDATION, West Lafayette, IN (US)

(21) Appl. No.: 14/000,883

(22) PCT Filed: Feb. 21, 2012
(86) PCT No.: PCT/US2012/025877

§ 371 Date: Oct. 31, 2013

Related U.S. Application Data
(60) Provisional application No. 61/445,185, filed on Feb. 22, 2011.

(51) Int. Cl. H01L 35/16; H01L 35/34; H01L 35/24

(52) U.S. Cl. CPC H01L 35/16; H01L 35/24; H01L 35/34
USPC 136/238; 136/201

(57) ABSTRACT

Thermoelectric materials and flexible polymer-based thermoelectric materials that may be applied to fabrics for use as personal cooling/heating clothes and portable power source.

### CROSS-REFERENCE TO RELATED APPLICATIONS

The present application claims priority to United States provisional patent application entitled, “Flexible Polymer-based Thermoelectric Materials and Fabrics Incorporating the Same,” having U.S. Ser. No. 61/445,185 and filed on Feb. 22, 2011, the disclosure of which is hereby incorporated by reference.

### INTRODUCTION TO THE INVENTION

The present disclosure is directed to thermoelectric materials, more specifically, to flexible polymer-based thermoelectric materials that may be applied to fabrics for use as personal cooling/heating clothes and portable power source.

Thermoelectric materials directly convert temperature difference into electric voltage and vice versa. Thermoelectric materials can be used to generate electricity from waste heat or used as a heater or cooler when electrically powered. The performance of a thermoelectric material is evaluated by a quantity called the figure of merit, ZT. The figure of merit can be expressed as an equation:
1.

ZT=S²·σ·T/κ

where:
2. S is the Seebeck coefficient,
3. σ is the electrical conductivity of the thermoelectric material,
4. T is the temperature, and
5. κ is the thermal conductivity.

Greater values of ZT indicate greater thermodynamic efficiency and better device performance.

Currently, American soldiers are conducting warfare in Afghanistan, where the daily high temperature is often above 110° F. during the summer. Additionally, soldiers are usually required to carry heavy loads. Therefore, the soldiers could benefit greatly from personal cooling devices. In order for such a device to be practical, it must be lightweight and must not hinder the soldier from his/her usual activity.

The instant disclosure provides a flexible polymer-based thermoelectric material on cloth (e.g., nylon) to provide bodily cooling. In fact, the thermoelectric material-based clothing may be used to charge batteries using a soldier's body heat when cooling is not desired. Also, the flexible nature of the thermoelectric material on clothing allows the cooling device to be similar to the soldiers other required clothing and therefore does not hinder normal movement. Moreover, the novel clothing may be used to reduce the infrared signal (through the cooling of outmost surface of soldiers) to reach a goal of being thermally stealth.

### BRIEF DESCRIPTION OF THE DRAWINGS

FIG. 1 are transmission electron microscope images of Te nanowires fabricated in accordance with the instant disclosure.

FIG. 2 are transmission electron microscope images of PbTe nanowires (A, B) and Bi₂Te₃ nanowires (C, D) fabricated in accordance with the instant disclosure.

FIG. 3 is a plot showing X-ray diffraction of PbTe, Bi₂Te₃, and Te nanowires.

FIG. 4 is a plot of conductivity as a function of temperature for a PbTe nanowire bulk sample compressed by spark plasma sintering in accordance with the instant disclosure.

FIG. 5 is a plot of Seebeck coefficient versus temperature for a PbTe nanowire bulk sample compressed by spark plasma sintering in accordance with the instant disclosure.

FIG. 6 is a plot of theoretical and actual scaled amplitude versus frequency for a PbTe nanowire bulk sample compressed by spark plasma sintering in accordance with the instant disclosure.

FIG. 7 is a plot of figure of merit versus temperature for a PbTe nanowire bulk sample compressed by spark plasma sintering in accordance with the instant disclosure.

FIG. 8 is a diagram of an exemplary thermoelectric device.

FIG. 9 is a photograph of a thin film of a 50% PEDOT:PSS 50% PbTe mixture coated on a nylon substrate in a straight orientation.

FIG. 10 is a photograph of the device of FIG. 9, shown in a flexed position without any readily apparent cracking of the coating.

### DETAILED DESCRIPTION

The exemplary embodiments of the present disclosure are described and illustrated below to encompass thermoelectric materials and, more specifically, to nanostructured thermoelectric materials and methods of utilizing and creating nanostructured materials including, without limitation, lead telluride-based materials. Of course, it will be apparent to those of ordinary skill in the art that the preferred embodiments discussed below are exemplary in nature and may be reconfigured without departing from the scope and spirit of the present invention. However, for clarity and precision, the exemplary embodiments as discussed below may include optional steps, methods, and features that one of ordinary skill should recognize as not being a requisite to fall within the scope of the present invention.

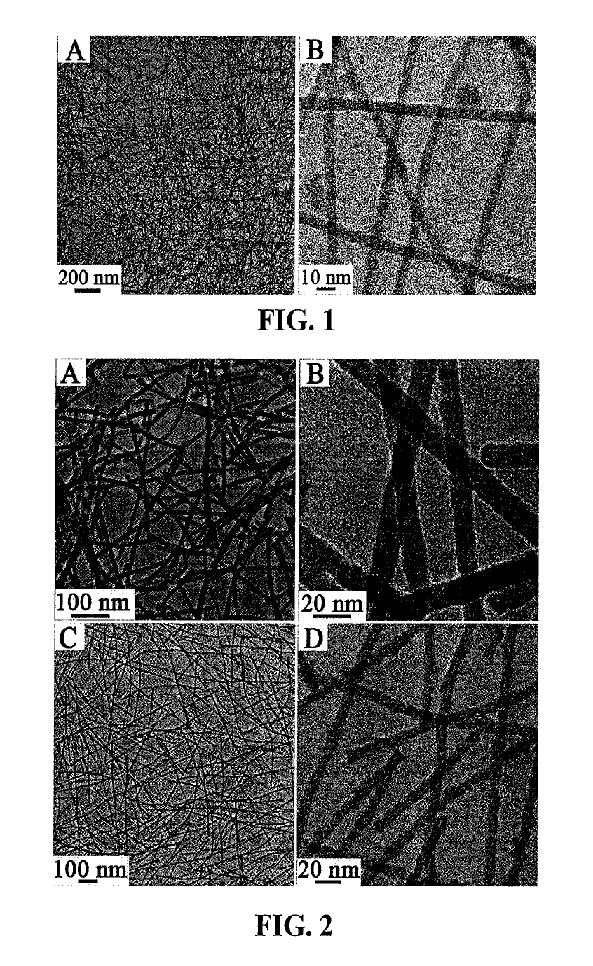

Referencing FIGS. 1-3, an exemplary thermoelectric coated cloth includes providing a method for synthesis of ultrathin PbTe and Bi₂Te₃ nanowires. The nanowires provide diameters of about or less than 10 nm. Ultrathin Te nanowires were used as the in-situ templates. The phase transfer from Te to PbTe or BiₓTe₁₋ₓ is accomplished through the injection of Pb and Bi precursor solution to the Te nanowire solution.

The PbTe and Bi₂Te₃ ultrathin nanowires are fabricated through a two-step process. First, the Te nanowires are synthesized as in-situ templates. In a typical synthesis, 10-30 ml of ethylene glycol, 0.1-1 g of polyvinylpyrrolidone (PVP) 0.2-0.8 g of alkali (NaOH or KOH), and 0.2-2 mmol of tellurium dioxide (TeO₂) or tellurite salts (Na₂TeO₃, or K₂TeO₃) are dissolved in ethylene glycol by heating to form a transparent solution, followed by adding 0.2-1 ml hydrazine hydrate solution into the as-prepared solution at 100-180° C. After about 20 minutes, the ultra-thin Te nanowires with average diameters of 5.5±0.5 nm and lengths up to several micrometers can be obtained, as shown in FIG. 1.

Second, using the as-synthesized ultrathin Te nanowires as the in-situ templates, the metal telluride nanowires can be produced by injecting corresponding metal precursors into the Te nanowire solution. The PbTe nanowires with diameters of 9.5±0.5 nm and Biₓ Te₁₋ₓ nanowires with diameters of 7.5±0.5 nm (FIGS. 2A, 2B, 2C, and 2D) were obtained by injecting lead acetate tri-hydrate (Pb(CH₃COO)₂.3H₂O) and bismuth nitrate penta-hydrate (Bi(NO₃)₃.5H₂O) in ethylene glycol precursor solution, respectively and reacting for about 30 minutes. The quantity of the injected metal precursor is calculated according to the molar ratio of elements in corresponding compounds. The resultant is a solution containing PbTe nanowires or Biₓ Te₁₋ₓ nanowires, respectively.

After the Te nanowires have been converted to PbTe or Biₓ Te₁₋ₓ nanowires, the ethylene glycol, alkali, and surfactant (PVP) are separated from the nanowires using a multi-step centrifuging process. Initially, a container housing a solution containing the nanowires is centrifuged for three hours at 8000 rpm. Afterwards, the supernatant was removed from the centrifuged contents, with the contents at the bottom of the container thereafter going through a washing process.

The washing process includes mixing the contents at the bottom of the centrifuged container with deionized water. More specifically, the bottom contents are combined with deionized water and centrifuged for one hour at 8000 rpm. After centrifuging is complete, the supernatant is removed and the bottom contents are again washed using the same washing process. Again, the supernatant is removed, but this time the bottom contents are subjected to a different washing process.

The second washing process involves mixing the bottom contents with ethanol (30 mL) and hydrazine monohydrate (5 mL@80%). After the ethanol and hydrazine are added, the entire contents are mixed and thereafter allowed to sit for approximately one hour. The contents are then centrifuged for thirty minutes at 8000 rpm. Again, the supernatant is removed after centrifugation, leaving the PbTe nanowires or Biₓ Te₁₋ₓ nanowires, respectively, as the retained solids.

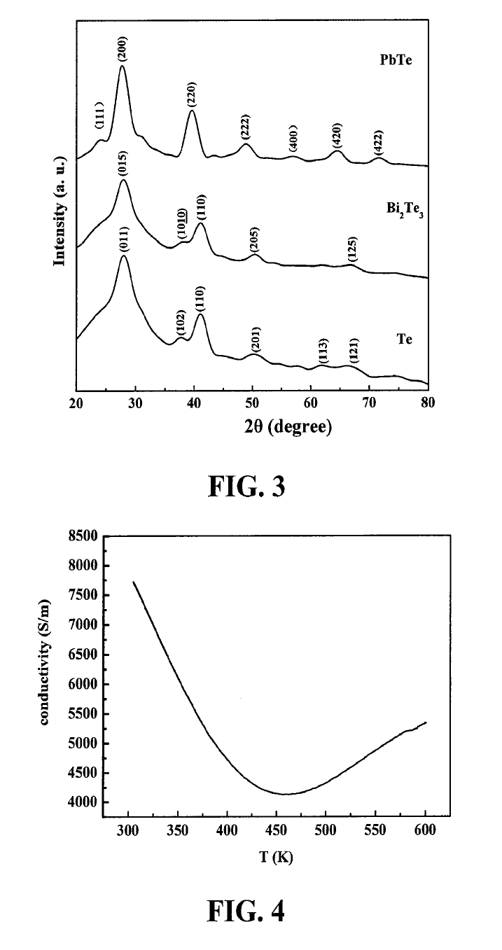

In order to clearly indicate the phase transfer from Te to PbTe or Bi₂Te₃ nanowires, the X-ray diffraction patterns of these three materials were obtained and depicted in FIG. 3. As can be seen in FIG. 3, the nanowires can be indexed to pure Te, PbTe and Bi₂Te₃, respectively, indicating the formation of PbTe and Bi₂Te₃ after the injection of the Pb or Bi precursor solution.

PbTe and Bi₂Te₃ are well suited candidates for thermoelectric conversion at a temperature of about 500 K and room temperature, respectively. By fabricating the nanowires with diameters less than 10 nm, the thermal conductivity can be significantly reduced and the Seebeck coefficient can be largely improved which will greatly contribute to enhance the thermoelectric figure of merits (ZT). The solution phase method is easily scalable and reproducible for large-scale deployment of thermoelectric conversion devices.

The nanowires are uniform and crystalline and their diameters less than 10 nm (PbTe: 9.5±0.5 nm, Bi₂Te₃: 7.5±0.5 nm) and lengths are up to micrometer scale. In addition, both PbTe and Bi₂Te₃ nanowires possess a rough surface. These properties will contribute to reduce the thermal conductivity of the materials. Also, the composition of the PbTe and Bi₂Te₃ nanowires can be controlled by adjusting the molar ratio between the Pb or Bi precursor and TeO₂. This feature may help to determine the most efficient material systems for the application of thermoelectric devices. The disclosed method can also be extended to other metal telluride nanowire synthesis by simply changing the precursor solution.

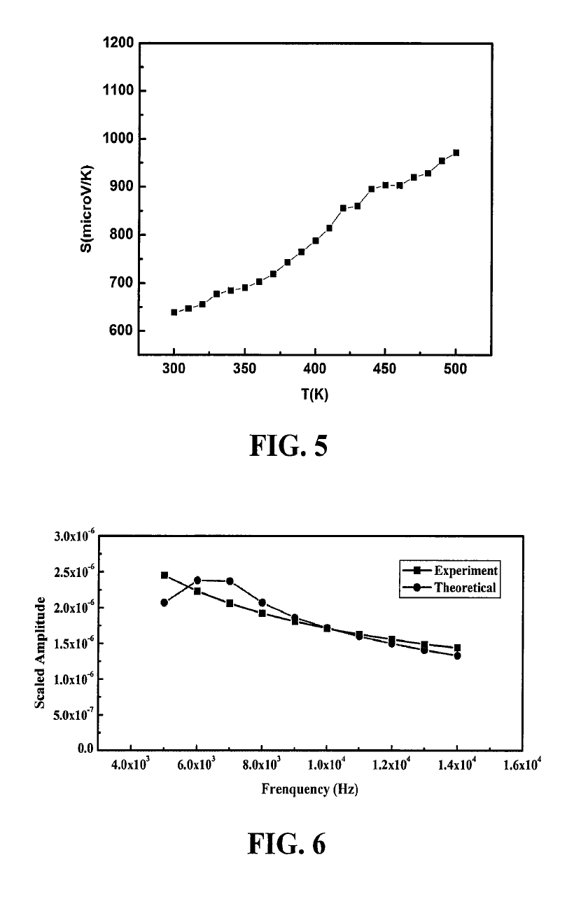

Referring to FIG. 4, thermoelectric properties of a PbTe nanowire sample fabricated in accordance with the instant disclosure were measured using a spark plasma sintering technique. As can be seen in the plot of FIG. 4, the electrical conductivity of the sample is around 7714 S/m at 300 K. It first decreases with increased temperature until 460 K and reaches a minimum value of 4126 S/m at this point, then increases with increased temperature. Compared with a commercially available bulk sample of PbTe nanowires, the electrical conductivity of our PbTe nanowire sample is much lower, which is about one fourth of that of bulk sample. However, as shown in FIG. 5, the Seebeck coefficient for a PbTe nanowire sample fabricated in accordance with the instant disclosure is largely enhanced compared with that of bulk sample, which is 2 to 4 times higher than that of bulk sample.

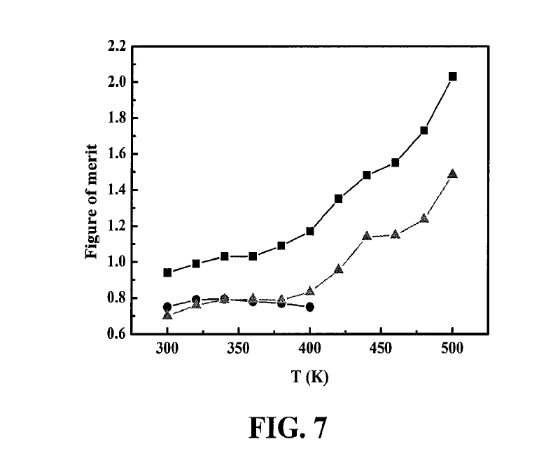

Referencing FIG. 6, thermal conductivity of a PbTe nanowire sample fabricated in accordance with the instant disclosure were measured using a phonon acoustic based method. FIG. 6 shows the curves of experimental and fitting data for PbTe nanowire bulk sample at room temperature, giving a total thermal conductivity value of about 1 Wm⁻¹K⁻¹, which is around 2 times lower than bulk or other reported data. Based on the data collected, calculated ZT values versus temperature were plotted in FIG. 7.

Fabrication of an exemplary flexible thermoelectric material includes blending poly(3,4-ethylenedioxythiophen):polystyrenesulfonate (PEDOT:PSS) with the PbTe (or Biₓ Te₁₋ₓ) nanowires fabricated in accordance with the instant disclosure. This process includes adding equal parts “Clevios PH1000” and water in order to obtain a desired weight ratio of PEDOT:PSS to PbTe (or Biₓ Te₁₋ₓ). Clevios PH1000 is a 1% PEDOT:PSS solution in water that is manufactured by Heraeus Materials Technology (www.clevios.com). To obtain smooth films of the (PEDOT:PSS):PbTe mixture, the water in the (PEDOT:PSS):PbTe solution is replaced by ethylene glycol by the following procedure. About equal volume parts ethylene glycol and (PEDOT:PSS):PbTe/water mixture are combined in a container and mixed briefly and treated by ultrasonic for 3 minutes. Then the container is exposed to nitrogen flow, heated to 70° C., while the solution is mixed by stirring. After about 12 hours, the water has evaporated, yielding a liquid solution of (PEDOT:PSS):PbTe in ethylene glycol. This solution is drop cast or spun cast onto a glass substrate in a nitrogen environment. The ethylene glycol is then evaporated by placing the still-wet film in a vacuum chamber at room temperature and a gauge pressure of about −29 inches of mercury. After about 24 hours in the vacuum chamber, the film is visibly dry and it is placed on a 80° C. hot plate for 1-3 hours to cause any residual ethylene glycol to evaporate.

The foregoing process yields a thin film of the (PEDOT:PSS):PbTe/Biₓ Te₁₋ₓ mixture coated on a substrate. As the exemplary substrate is nylon having relatively small pore sizes (1 micron or smaller) the exemplary thermoelectric film does not diffuse throughout the interior of the substrate. Instead, the film stays on the surface of the substrate.

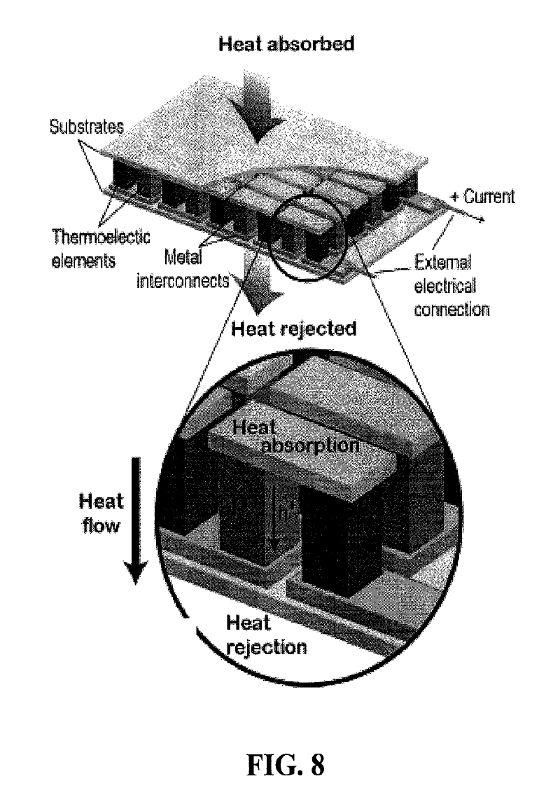

Referring to FIG. 8, an exemplary diagram of a thermoelectric device is shown. In exemplary form, the thermoelectric material adhered to the substrate may be combined with other thermoelectric materials to create a working thermoelectric device. In exemplary form, the thermoelectric device comprises a first electrically conductive material, followed by a first thermoelectric material layer (thin film of the (PEDOT:PSS):PbTe/Biₓ Te₁₋ₓ mixture), and a second electrically conductive layer. These three layers should be formed into small patches. A complete device should contain patches of n- and p-type material connected electrically in series with the electrically conductive layers as shown in FIG. 8. The current loop is then completed by connecting the device to an external power source or load to provide cooling or power generation, respectively.

A fabric, such as nylon, may be provided to contact the first and second conductive layers to provide a composite comprising: (1) a first layer of nylon; (2) the first electrically conductive material; (3) the first thermoelectric material layer; (4) the second electrically conductive material; and, (5) a second layer of nylon.

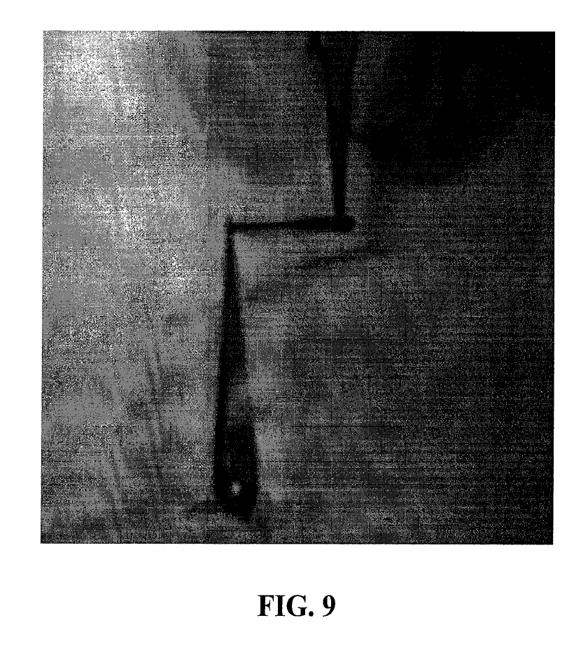

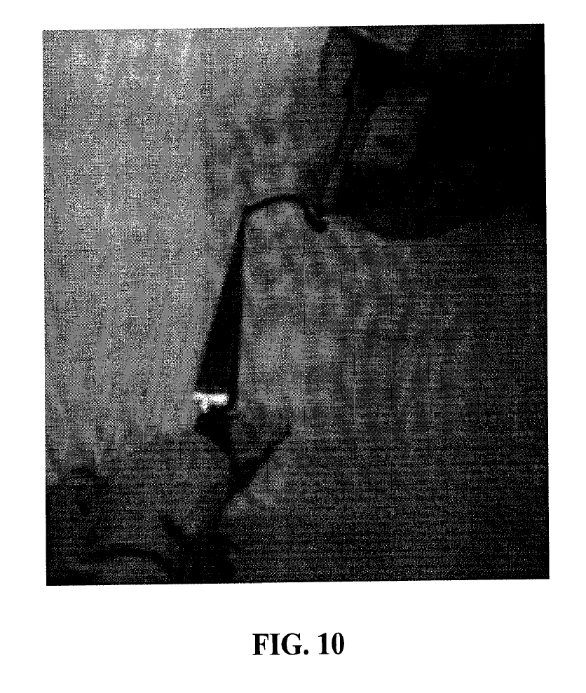

Referring to FIGS. 9 and 10, a nylon substrate was coated with a thin film of a 50 wt. % PEDOT:PSS 50 wt. % PbTe mixture, while the nylon substrate was maintained in a relatively straight orientation. The coating was created by drop casting a liquid mixture of 50 wt. % PEDOT:PSS 50 wt. % PbTe dissolved in water onto a piece of nylon and allowing the water to evaporate by heating on a hot plate at 50° C. in air. Once the coating appeared dry, the coated nylon was moved to a nitrogen environment where it was placed on a 130° C. hot plate for 10 minutes. After the coating was applied to the nylon substrate and cured, the nylon substrate was flexed or bent to arrive at the orientation shown in FIG. 10. In this flexed orientation, it should be noted that the coating did not exhibit readily apparent cracking, thereby evidencing flexibility of the coating. Films with similar flexibility were made by drop casting liquid mixtures of water, PEDOT:PSS and PbTe with other weight ratios of PEDOT:PSS to PbTe (20, 30, 40, 50, 60, 70, 80, 90, 100 wt. % PEDOT:PSS, with the balance of solids being PbTe nanowires). In all cases, the water was evaporated by placing the liquid coated nylon on a hot plate a 50° C. Films with similar flexibility were also made by drop casting liquid mixture of ethylene glycol, PEDOT:PSS, and PbTe with weight ratios of PEDOT:PSS to PbTe (20, 40, 60, 80 wt. % PEDOT:PSS, with the balance of solids being PbTe nanowires). The ethylene glycol was evaporated from these films by placing the liquid coated nylon on a hot plate at 80° C. for 2-4 hours.

Following from the above description and disclosure summaries, it should be apparent to those of ordinary skill in the art that, while the methods and apparatuses herein described constitute exemplary embodiments of the present disclosure, the invention contained herein is not limited to this precise embodiment and that changes may be made to such embodiments without departing from the scope of the invention as defined by the claims. Additionally, it is to be understood that the invention is defined by the claims and it is not intended that any limitations or elements describing the exemplary embodiments set forth herein are to be incorporated into the interpretation of any claim element unless such limitation or element is explicitly stated. Likewise, it is to be understood that it is not necessary to meet any or all of the identified advantages or objects of the disclosure in order to fall within the scope of any claims, since the invention is defined by the claims and since inherent and/or unforeseen advantages of the present invention may exist even though they may not have been explicitly discussed herein.

What is claimed is:

1. A conductive and flexible film comprising:
a polymer; and,
telluride nanowires.

2. The conductive and flexible film of claim 1, wherein the polymer comprises at least one of a polyethylene and a polystyrene.

3. The conductive and flexible film claim 1, wherein the telluride nanowires comprise bismuth telluride nanowires.

4. The conductive and flexible film of claim 1, wherein the telluride nanowires comprise lead telluride nanowires.

5. The conductive and flexible film of claim 1, wherein the polymer comprises a conductive polymer.

6. The conductive and flexible film of claim 1, wherein the polymer comprises a polystyrene that includes poly(3,4-ethylenedioxythiophen):polystyrenesulfonate (PEDOT:PSS).

7. A method of fabricating a flexible conductive film, the method comprising:
mixing nanowires with a polymer to create a mixture; and,
applying the mixture onto a substrate to create a flexible conductive film.

8. The method of claim 7, wherein the polymer comprises at least one of a polyethylene, and a polystyrene.

9. The method of claim 7, wherein the nanowires comprise bismuth telluride nanowires.

10. The method of claim 7, wherein the nanowires comprise lead telluride nano wires.

11. The method of claim 7, wherein the polymer is conductive.

12. The method of claim 7, wherein the act of applying the mixture onto the substrate includes drop casting the mixture onto the substrate to create the flexible conductive film.

13. The method of claim 7, wherein the polymer comprises a polystyrene that includes poly(3,4-ethylenedioxythiophen):polystyrenesulfonate (PEDOT:PSS).

14. The method of claim 7, wherein the polymer is a conductive polymer.

15. A thermoelectric device comprising:
a thermoelectric layer; and,
a fabric substrate to which the thermoelectric layer is adhered.

16. The thermoelectric device of claim 15, wherein the thermoelectric layer comprises: a polymer; and,
nanowires.

17. The thermoelectric device of claim 16, wherein the polymer comprises poly(3,4-ethylenedioxythiophen):polystyrenesulfonate (PEDOT:PSS).

18. The thermoelectric device of claim 16, wherein the nanowires comprise bismuth telluride nanowires.

19. The thermoelectric device of claim 16, wherein the nanowires comprise lead telluride nanowires.

20. The thermoelectric device of claim 16, wherein the polymer is conductive.
